(19) United States
(12) Patent Application Publication
(10) Pub. No.: US 2025/0255158 A1
(43) Pub. Date: Aug. 7, 2025

(54) DISPLAY DEVICE

(71) Applicant: LG Display Co., Ltd., Seoul (KR)

(72) Inventors: KyooHo LEE, Goyang-si (KR); KyoungJin NAM, Paju-si (KR)

(73) Assignee: LG Display Co., Ltd., Seoul (KR)

(21) Appl. No.: 18/821,522

(22) Filed: Aug. 30, 2024

(30) Foreign Application Priority Data
Feb. 2, 2024 (KR) 10-2024-0016601

(51) Int. Cl. H10K 59/80; H10K 59/124

(52) U.S. Cl. CPC H10K 59/879; H10K 59/124

(57) ABSTRACT

A display device includes a substrate including a plurality of sub-pixels; a first planarization layer on the substrate, the first planarization layer having an open area between adjacent ones of the sub-pixels; a second planarization layer on the first planarization layer and in the open area, the first planarization layer has a first refractive index lower than a second refractive index of the second planarization layer; a first electrode on a portion of the second planarization layer; an organic layer on the anode and in the open area; and a second electrode on the organic layer and in the open area.

This application claims the priority of Korean Patent Application No. 10-2024-0016601 filed on Feb. 2, 2024, in the Korean Intellectual Property Office, the disclosure of which is incorporated herein by reference.

### BACKGROUND

### Technical Field

The present disclosure relates to a display device, and more particularly, to a display device that improves a light extraction efficiency.

### Discussion of the Related Art

As it enters the information era, a field of a display device that visually expresses electrical information signals has been rapidly developed and studies have continued to improve performances of various display devices, such as a thin profile, a light weight, and low power consumption.

A representative display device may include a liquid crystal display (LCD) device, a field emission display (FED) device, an electro-wetting display (EWD) device, an organic light emitting display (OLED) device, and the like.

An electroluminescent display device, such as an organic light emitting display device, is a self-emitting display device so that a separate light source is not necessary, unlike the arrangement in a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

The electroluminescent display device configures a light emitting diode by disposing a plurality of organic layers each including a light emitting layer between two electrodes of an anode and a cathode. For example, when holes are injected from the anode into the light emitting layer and electrons are injected from the cathode into the light emitting layer, the injected holes and electrons are recombined in the light emitting layer to form excitons and emit light.

However, the electroluminescent display device has a problem in that there is light, among light emitted from a light emitting layer, that does not go out from a display panel and is trapped in the display panel. Thus, a light extraction efficiency and luminous efficiency is degraded.

### SUMMARY

Accordingly, embodiments of the present disclosure are directed to a display device that substantially obviates one or more of the problems due to limitations and disadvantages of the related art.

An aspect of the present disclosure is to provide a display device that suppresses light leakage and improves a light extraction efficiency.

Another aspect of the present disclosure is to provide a display device that minimizes color mixture with surrounding sub pixels.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including a plurality of sub-pixels; a first planarization layer on the substrate, the first planarization layer having an open area between adjacent ones of the sub-pixels; a second planarization layer on the first planarization layer and in the open area, the first planarization layer has a first refractive index lower than a second refractive index of the second planarization layer; a first electrode on a portion of the second planarization layer; an organic layer on the anode and in the open area; and a second electrode on the organic layer and in the open area.

In another aspect, a display device, having at least a first sub-pixel and a second sub-pixel, comprises a substrate; a first layer on the substrate, the first layer having an open area between the first sub-pixel and the second sub-pixel; a second layer on the first layer and in the open area, the first layer having a first refractive index that is lower than a second refractive index of the second layer; and organic light emitting devices on the second layer in each of the first sub-pixel and the second sub-pixel.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a block diagram illustrating a display device according to example embodiments of the present disclosure;

FIG. 2 is a view schematically illustrating a circuit configuration of a sub pixel according to example embodiments of the present disclosure;

FIG. 3 is a view illustrating a cross-sectional structure and a planar structure of a display panel according to a first example embodiment of the present disclosure;

FIG. 4 is a view illustrating a cross-section of a part of a sub pixel of FIG. 3;

FIG. 5 is a view illustrating a cross-sectional structure and a planar structure of a display panel according to a second example embodiment of the present disclosure;

FIGS. 6A to 6C are views illustrating an optical path according to the number of inclination angles;

FIG. 7 is a view illustrating a cross-sectional structure and a planar structure of a display panel according to a third example embodiment of the present disclosure;

FIG. 8 is a view illustrating a cross-section of a part of a sub pixel of FIG. 7;

FIG. 9 is a view illustrating a cross-sectional structure and a planar structure of a display panel according to a fourth example embodiment of the present disclosure;

FIG. 10 is a view illustrating a cross-sectional structure and a planar structure of a display panel according to a fifth example embodiment of the present disclosure; and

FIG. 11 is a view illustrating a cross-section of a part of a sub pixel of FIG. 10.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an example embodiment of the present disclosure will be described in detail with reference to the drawings.

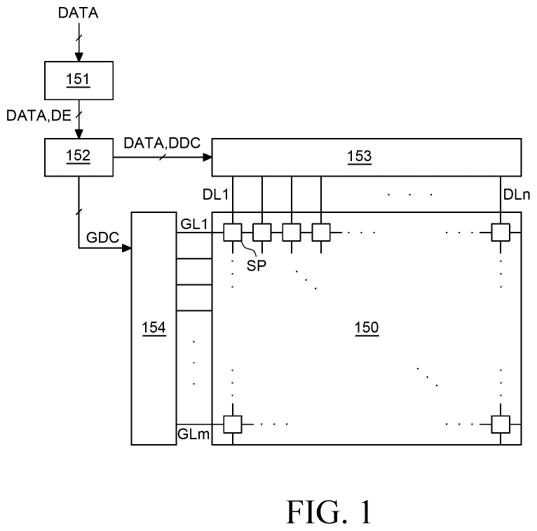

FIG. 1 is a block diagram illustrating a display device according to example embodiments of the present disclosure.

With reference to FIG. 1, a display device according to example embodiments of the present disclosure may include an image processor 151, a timing controller 152, a data driver 153, a scan driver 154, and a display panel 150.

The image processor 151 may output a data enable signal DE, etc. together with a data signal DATA supplied from the outside. Further, for example, the image processor 151 may output one or more of a vertical synchronization signal, a horizontal synchronization signal, and a clock signal in addition to the data enable signal DE.

The timing controller 152 may be supplied with the data signal DATA together with the data enable signal DE or a driving signal including the vertical synchronization signal, the horizontal synchronization signal, and the clock signal from the image processor 151. The timing controller 152 may output a gate timing control signal GDC for controlling an operation timing of the scan driver 154 and a data timing control signal DDC for controlling an operation timing of the data driver 153, based on the driving signal.

The data driver 153 samples and latches the data signal DATA supplied from the timing controller 152 in response to the data timing control signal DDC supplied from the timing controller 152 to convert the data signal into a gamma reference voltage and output the converted gamma reference voltage. The data driver 153 may output the data signal DATA through data lines DL1 to DLn. The data driver 153 may be formed as an integrated circuit (IC).

Further, the scan driver 154 may output the scan signal in response to the gate timing control signal GDC supplied from the timing controller 152. The scan driver 154 may output the scan signal through gate lines GL1 to GLm. The scan driver 154 may be formed as an integrated circuit (IC) or formed in the display panel 150 in a gate in panel manner.

The display panel 150 may display images in response to the data signal DATA and the scan signal supplied from the data driver 153 and the scan driver 154.

The display panel 150 may include a sub pixel SP to display an image.

For example, the sub pixel SP may include a red sub pixel, a green sub pixel, and a blue sub pixel or include a white sub pixel, a red sub pixel, a green sub pixel, and a blue sub pixel. The sub pixel SP may have one or more emission areas according to an emission characteristic.

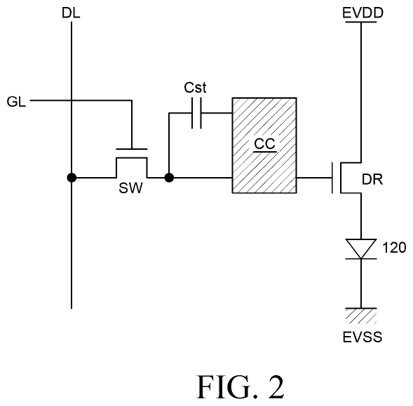

FIG. 2 is a view schematically illustrating a circuit configuration of a sub pixel according to example embodiments of the present disclosure.

With reference to FIG. 2, in one sub pixel, a switching transistor SW, a driving transistor DR, a capacitor Cst, a compensation circuit CC, and a light emitting diode 120 may be included.

For example, the switching transistor SW may perform a switching operation such that a data signal supplied through the data line DL is stored in a capacitor Cst as a data voltage in response to a scan signal supplied through the gate line GL. Further, for example, the driving transistor DR may operate to flow a driving current between a first power line EVDD (a high potential voltage) and a second power line EVSS (a low potential voltage) in accordance with the data voltage stored in the capacitor Cst. Further, the light emitting diode 120 may operate to emit light in accordance with a driving current formed by the driving transistor DR.

The compensation circuit CC is a circuit added in the sub pixel to compensate for a threshold voltage, etc. of the driving transistor DR. The compensation circuit CC may be configured by one or more transistors. A configuration of the compensation circuit CC may vary depending on an external compensating method. For example, each sub pixel structure may be a 2T (transistor) 1C (capacitor) structure, but it is not limited thereto, so that the sub pixel structure may further include one or more transistors and if necessary, further include one or more capacitors. Alternatively, the plurality of sub pixels may have the same structure or some of the plurality of sub pixels may have a different structure.

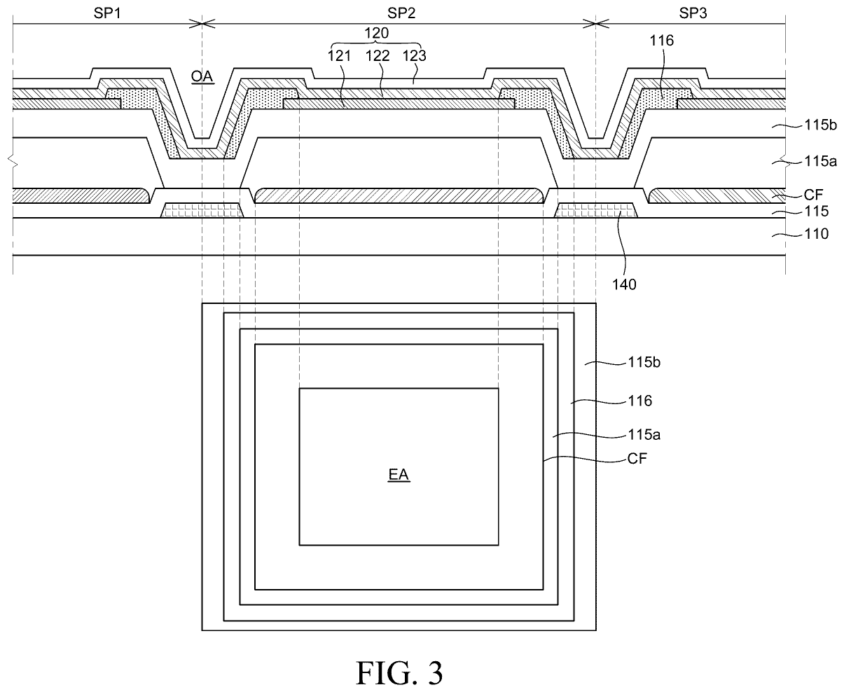

FIG. 3 is a view illustrating a cross-sectional structure and a planar structure of a display panel according to a first example embodiment of the present disclosure.

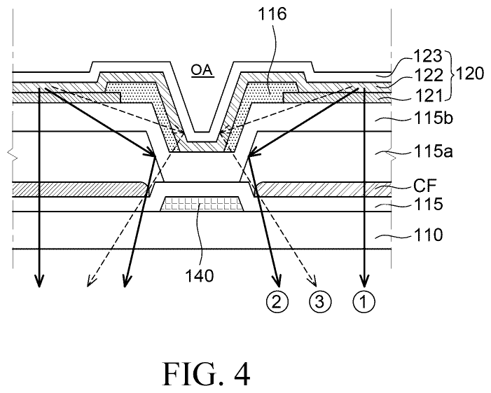

FIG. 4 is a view illustrating a cross-section of a part of a sub pixel of FIG. 3.

FIG. 3 schematically illustrates cross-sectional structures of the first sub pixel SP1, the second sub pixel SP2, and the third sub pixel SP3 and a planar structure corresponding to the second sub pixel SP2. FIG. 3 schematically illustrates planar structures of configurations corresponding to the second sub pixel SP2, excluding the organic layer 122 and the cathode 123 above the anode 121, for the sake of convenience.

FIG. 4 illustrates a cross-sectional structure of a part of the first sub pixel SP1 and the second sub pixel SP2 illustrated in FIG. 3 together with a path of emitted light. For example, FIG. 4 illustrates a cross-sectional structure of a boundary of the first sub pixel SP1 and the second sub pixel SP2.

In FIGS. 3 and 4, for the convenience of description, a TFT substrate 110 is illustrated by omitting various circuit configurations including a thin film transistor provided on the substrate and wiring lines. Even though in FIGS. 3 and 4, components above the light emitting diode 120 are not illustrated for the convenience of description, the present disclosure is not limited thereto, and the present disclosure may include an adhesive layer, an encapsulation substrate, and the like above the light emitting diode 120.

Further, in FIGS. 3 and 4, a bottom-emission type organic light emitting display device is mainly described, but the present disclosure is not limited thereto and is also applicable to a top-emission type or a dual-emission type organic light emitting display device.

As illustrated in FIGS. 3 and 4, the display panel may include a pixel area in which a plurality of sub pixels SP1, SP2, and SP3 is provided and a peripheral area (not illustrated) in which various circuit configurations and wiring lines are disposed.

A plurality of first sub pixels SP1, second sub pixels SP2, and third sub pixels SP3 may be disposed in the pixel area. However, the present disclosure is not limited thereto and may further include a fourth sub pixel.

For example, the first sub pixel SP1 may be a green sub pixel. For example, the second sub pixel SP2 may be a blue sub pixel. For example, the third sub pixel SP3 may be a red sub pixel. When the plurality of sub pixels SP1, SP2, and SP3 further includes a fourth sub pixel, the fourth sub pixel may be a white sub pixel.

For example, the first sub pixel SP1, the second sub pixel SP2, and the third sub pixel SP3 may have a circular shape or a polygonal shape but are not limited thereto. Here, a shape of the sub pixels SP1, SP2, and SP3 is defined by the shape of the first electrode (anode) 121, but it is not limited thereto. In FIG. 3, it is illustrated that the first sub pixel SP1, the second sub pixel SP2, and the third sub pixel SP3 have a rectangular shape.

Even though it is not illustrated in the drawings, the TFT substrate 110 may include various circuit configurations including a thin film transistor provided on the substrate and wiring lines. For example, a driving transistor and a switching transistor may be disposed above the substrate.

A signal line 140 may be disposed above the TFT substrate 110 on which various circuit configurations and the wiring lines are disposed. The signal line 140 may be a data line that transmits a data signal but is not limited thereto.

For example, the signal line 140 may be disposed at the boundary between the first sub pixel SP1, the second sub pixel SP2, and the third sub pixel SP3, but it is not limited thereto.

A protection layer 115 may be disposed above the signal line 140.

For example, the protection layer 115 may be configured by silicon oxide (SiOx), silicon nitride (SiNx), or a double-layered structure thereof, but it is not limited thereto and may be configured by an organic material such as acrylic resin or epoxy resin.

A color filter layer CF may be disposed on the protection layer 115.

The color filter layer CF of each sub pixel SP1, SP2, SP3 may have any one color of red, green, and blue. Further, in a sub pixel in which white is implemented, the color filter layer CF may not be disposed. Red, green, and blue may be disposed in various forms.

The color filter layer CF may be disposed in each of the plurality of sub pixels SP1, SP2, and SP3 or may be disposed only in some sub pixels SP1, SP2, and SP3, among the plurality of sub pixels SP1, SP2, and SP3.

The color filter layer CF may be disposed in a position corresponding to an emission area EA of each sub pixel SP1, SP2, SP3. The emission area EA refers to an area in which a light emitting layer of the organic layer 122 emits light by the first electrode (for example, an anode) 121 and the second electrode (for example, a cathode) 123.

In a plan view, the color filter layer CF may have a substantially (or overall) rectangular shape, but is not limited thereto, and may have a circular, oval, or polygonal shape. Further, in a plan view, the color filter layer CF may have an area larger than the emission area EA.

Transparent layers or planarization layers 115a and 115b may be disposed above the color filter layer CF. For example, the planarization layers 115a and 115b may include a first planarization layer 115a (or first transparent layer) and a second planarization layer 115b (or second transparent layer). The planarization layers 115a and 115b may be overcoat layers.

The first planarization layer 115a may be disposed above the protection layer 115. The second planarization layer 115b may be disposed on the first planarization layer 115a.

For example, the first planarization layer 115a and the second planarization layer 115b may be configured by an organic material, such as acrylic resin including photo acryl or epoxy resin. For example, the second planarization layer 115b may be configured by an organic material having a higher refractive index than that of the first planarization layer 115a.

For example, the second planarization layer 115b may be disposed on a front surface of the TFT substrate 110 and the first planarization layer 115a may be patterned for every sub pixel SP1, SP2, SP3. For example, an open area OA that encloses the emission area EA may be disposed in the vicinity of the emission area EA of each sub pixel SP1, SP2, SP3. For example, a partial area of the first planarization layer 115a between the sub pixels SP1, SP2, and SP3 is removed to form the open area OA but is not limited thereto. The second planarization layer 115b may be disposed on the front surface of the TFT substrate 110 including the open area OA.

In the meantime, according to the related art, the second planarization layer is patterned on the totally deposited first planarization layer. In this case, if the thickness of the first planarization layer is small, the outgas of the color filter layer may not be blocked so that pixel shrinkage may occur. To suppress this problem, if the thickness of the first planarization layer is increased, light that travels from the second planarization layer having a high refractive index to the first planarization layer having a low refractive index enters an adjacent sub pixel through the first planarization layer so that light leakage may occur.

Therefore, according to the first example embodiment of the present disclosure, the first planarization layer 115a is patterned for every sub pixel SP1, SP2, SP3 to form the open area OA formed between the sub pixels SP1, SP2, and SP3 by removing a part of the first planarization layer 115a. The open area OA is filled with the second planarization layer 115b with a high refractive index to totally reflect light entering the adjacent sub pixel SP1, SP2, SP3. For example, between the sub pixels SP1, SP2, and SP3, the second planarization layer 115b with a high refractive index is interposed between the first planarization layers 115b with a low refractive index to totally reflect light entering the adjacent sub pixel SP1, SP2, SP3 to suppress the light leakage and improve the light extraction efficiency.

Further, in the first example embodiment of the present disclosure, the first planarization layer 115a is formed with an appropriate thickness so that the light leakage may be suppressed without causing pixel shrinkage.

For example, the protection layer 115 may have a refractive index of approximately 1.49 and the first planarization layer 115a may have a refractive index of approximately 1.46. Further, for example, the second planarization layer 115b may have a refractive index of approximately 1.63 and the bank 116 may have a refractive index of approximately 1.5.

For example, when a taper (approximately 40 degrees to 60 degrees) of the bank 116 is considered, a side surface (taper) of the first planarization layer 115a may have an inclination angle that is larger than a threshold angle (approximately 30 degrees) and smaller than 60 degrees. When the taper is 60 degrees or larger, the thickness is reduced during the deposition of the cathode 123 to cause defects. In response to the taper shape and angle of the first planarization layer 115a, the taper shape and angle of the second planarization layer 115b deposited thereon may be determined. The bank 116 may be covered by the organic layer 122.

Only an edge part of the first electrode is covered by the bank 116. The first electrode 121 is smaller in its length than the color filer CF or the first planarization layer 115a. The first electrode 121 is not disposed in the open area OA and/or is not at a side surface of the first planarization layer 115a or first layer.

The taper angle of the first planarization layer 115a may be determined according to a process condition of a dry etching process. For example, when the etching is performed for 50 seconds with NF₃:O₂ gas, approximately 45 degrees of taper is formed. Further, when the etching is performed for 60 seconds with NF₃:O₂ gas and for 50 seconds with O₂ gas, approximately 55 degrees of taper may be formed. Further, for example, when the etching is performed for 50 seconds with NF₃:O₂ gas and for 100 seconds with O₂ gas, approximately 60 degrees of taper is formed and when the etching is performed for 100 seconds with O₂ gas, approximately 65 degrees of taper may be formed.

As described above, when the refractive index of the high refractive material is larger than the refractive index of the low refractive material, most light may be totally reflected from the interface. Further, when a stepped structure is formed on the interface, the total reflection may occur in any position so that the light extraction efficiency may be maximized.

Among light \textcircled{1}, \textcircled{2}, and \textcircled{3} emitted from the light emitting layer, most light \textcircled{1} is extracted to the outside via the color filter layer CF and the TFT substrate 110. Some light \textcircled{2}, which travels from the second planarization layer 115b having a high refractive index to the first planarization layer 115a having a low refractive index, is totally reflected from the interface of the first planarization layer 115a and the second planarization layer 115b to be extracted to the outside via the corresponding color filter layer CF and TFT substrate 110. Further, some light \textcircled{3}, which travels from the second planarization layer 115b to the cathode 123 via the bank 116 and the organic layer 122, is reflected from the cathode 123 to be extracted to the outside via the corresponding color filter layer CF and TFT substrate 110. As described above, a part of light \textcircled{2} and \textcircled{3} that travels from a corresponding sub pixel SP1, SP2, SP3 to an adjacent sub pixel SP1, SP2, and SP3 is reflected to be extracted to the outside via the color filter layer CF and the TFT substrate 110 of the sub pixel SP1, SP2, SP3 to improve light extraction efficiency.

Therefore, low power may be implemented to reduce the power consumption and greenhouse gases generated by power use may be reduced to implement environment/social/governance (ESG).

In the meantime, in a plan view, the first planarization layer 115a may have a substantially (or overall) rectangular shape, but is not limited thereto, and may have a circular, oval, or polygonal shape. Further, in a plan view, the first planarization layer 115a may have a larger area than that of the color filter layer CF to cover the color filter layer CF.

Further, for example, in a plan view, the bank 116 may have a substantially (or overall) rectangular frame shape excluding a part of the open area OA and the emission area EA, but it is not limited thereto and may have a circular, oval, or polygonal frame shape.

For example, the bank 116 may be formed to cover a part of a top surface of the anode 121 and a side surface of the second planarization layer 115b that is filled in the open area OA. In FIGS. 3 and 4, it is illustrated that the bank 116 is separated for every sub pixel SP1, SP2, SP3, but it is not limited thereto and may be formed to be connected to each other between the sub pixels SP1, SP2, and SP3.

The taper shape and angle of the bank 116 disposed on the second planarization layer 115b may be determined in response to the taper shape and angle of the second planarization layer 115b filled (deposited) in the open area OA.

For example, the anode 121 may be disposed in a part of the top surface of the second planarization layer 115b. A part of an end of the anode 121 may be covered by the bank 116. A part of the anode 121 that is not covered by the bank 116 to be exposed may configure the emission area EA. For example, a part of the bank 116 corresponding to the emission area EA may be open in the sub pixel SP1, SP2, SP3.

For example, the anode 121 may be formed of a transparent conductive material, such as indium tin oxide (ITO), indium zin oxide (IZO), or indium gallium zinc oxide (IGZO).

The organic layer 122 may be disposed on the entire TFT substrate 110 including the open area OA.

The cathode 123 may be disposed on the organic layer 122.

The cathode 123 may include a reflective electrode or a reflective material. For example, the cathode 123 may include any one of a group consisting of metal materials, such as gold (Au), silver (Ag), aluminum (Al), molybdenum (Mo), palladium (Pd), copper (Cu), or magnesium (Mg), or an alloy thereof. Alternatively, the cathode 123 may be configured by laminating a layer formed of a transparent conductive layer such as indium tin oxide (ITO), indium zinc oxide (IZO), or indium gallium zinc oxide (IGZO) and a layer formed of a metal material such as gold (Au), silver (Ag), aluminum (Al), molybdenum (Mo), magnesium (Mg), palladium (Pd), copper (CU), or an alloy thereof, but is not limited thereto.

The light emitting diode 120 may be configured by the anode 121, the organic layer 122, and the cathode 123.

The encapsulation substrate may be disposed above the TFT substrate 110 in which the light emitting diode 120 is disposed with an adhesive layer interposed therebetween. However, it is not limited thereto, and a multi-layered encapsulation structure configured by an encapsulation member and a reinforcement substrate may be disposed above the TFT substrate 110.

In the meantime, as described above, according to the present disclosure, a step structure may be formed on a side surface of the first planarization layer, which will be described in more detail with reference to the drawing.

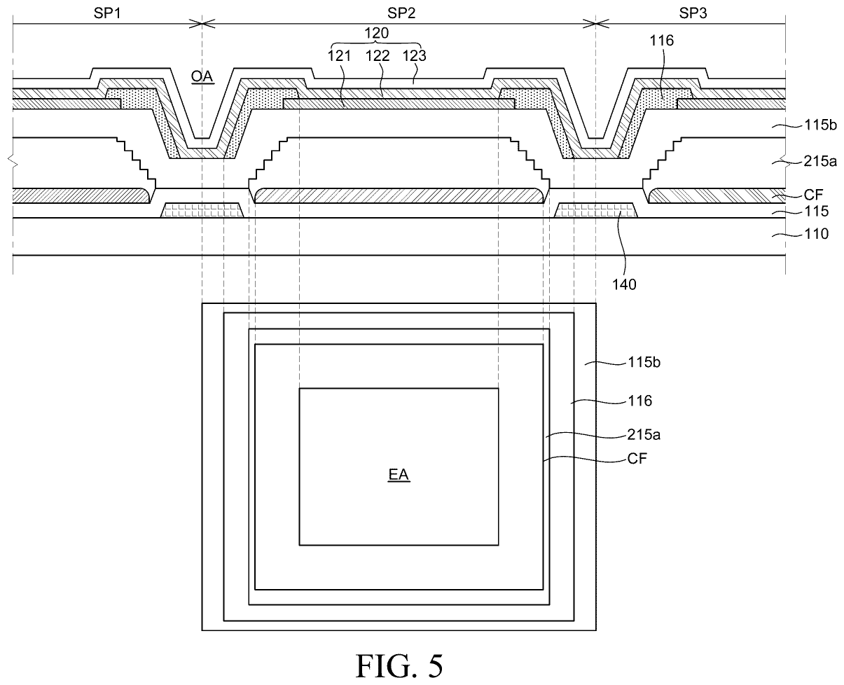

FIG. 5 is a view illustrating a cross-sectional structure and a planar structure of a display panel according to a second example embodiment of the present disclosure.

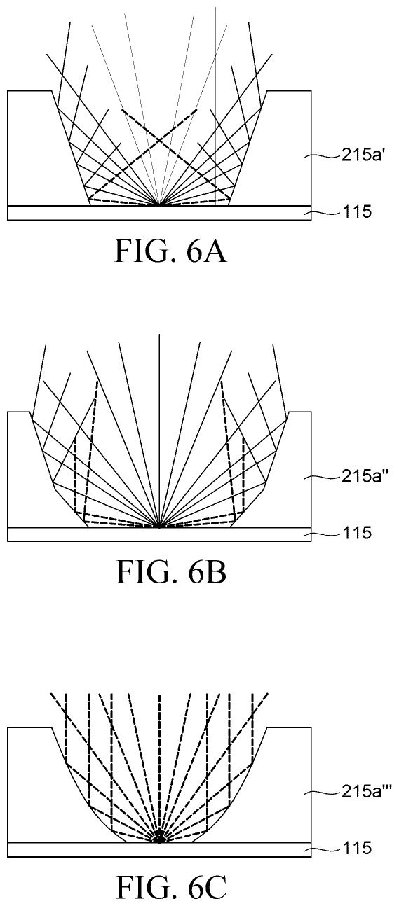

FIGS. 6A to 6C are views illustrating an optical path according to the number of inclination angles, more specifically, views of an optical path according to the number of inclination angles in the cross-section structure (or a cross-section view).

A second example embodiment of the present disclosure of FIG. 5 has a different side surface shape of a first planarization layer 215a from that of the first example embodiment of the present disclosure of FIGS. 3 and 4 described above. However, other configurations are substantially the same so that a redundant description will be omitted. The same configuration will be denoted with the same reference numeral. Here, the description for the same reference numeral may refer to FIGS. 1 to 4.

FIG. 5 schematically illustrates cross-sectional structures of the first sub pixel SP1, the second sub pixel SP2, and the third sub pixel SP3 and a planar structure corresponding to the second sub pixel SP2. FIG. 5 schematically illustrates planar structures of configurations corresponding to the second sub pixel SP2, excluding the organic layer 122 and the cathode 123 above the anode 121.

In FIG. 5, for the convenience of description, a TFT substrate 110 is illustrated by omitting various circuit configurations including a thin film transistor provided on the substrate and wiring lines. Even though in FIG. 5, components above the light emitting diode 120 are not illustrated for the convenience of description, the present disclosure is not limited thereto, and the present disclosure may include an adhesive layer, an encapsulation substrate, and the like above the light emitting diode 120.

Further, in FIG. 5, a bottom-emission type organic light emitting display device is mainly described, but the present disclosure is not limited thereto and is also applicable to a top-emission type or a dual-emission type organic light emitting display device.

As shown in FIG. 5, a color filter layer CF may be disposed on the protection layer 115. The color filter layer CF may be disposed in a position corresponding to an emission area EA of each sub pixel SP1, SP2, SP3.

A first planarization layer 215a may be disposed above the color filter layer CF. The second planarization layer 115b may be disposed on the first planarization layer 215a.

For example, the second planarization layer 115b may be configured by an organic material having a higher refractive index than that of the first planarization layer 215a.

As described above, the second planarization layer 115b may be disposed on the entire TFT substrate 110 and the first planarization layer 215a may be patterned for every sub pixel SP1, SP2, SP3.

For example, according to the second example embodiment of the present disclosure, the first planarization layer 215a is patterned for every sub pixel SP1, SP2, SP3 to form the open area OA formed between the sub pixels SP1, SP2, and SP3 by removing a part of the first planarization layer 215a. The open area OA is filled with the second planarization layer 115b with a high refractive index to totally reflect light entering the adjacent sub pixel SP1, SP2, SP3, thereby suppressing the light leakage and improving the light extraction efficiency. Further, in the second example embodiment of the present disclosure, the first planarization layer 215a may be formed with an appropriate thickness so that the light leakage may be suppressed without causing pixel shrinkage.

Further, according to the second example embodiment of the present disclosure, a side surface of the first planarization layer 215a has a step structure. Therefore, the side surface of the first planarization layer 215a and the side surface of the second planarization layer 115b may have a step structure. At this time, the step structure means that the side surface of the first planarization layer 215a on which total reflection occurs has a step shape having a plurality of angles, rather than a straight line shape having one angle (a shape of FIG. 3 described above).

For example, as illustrated in FIG. 6A, when the side surface of the first planarization layer 215a′ has a straight line shape having one angle, light reflected from the lower portion may be trapped therein without being extracted to the outside, due to a large reflection angle.

In contrast, as illustrated in FIG. 6B, when a side surface of the first planarization layer 215a″ is formed by two lines having different angles, a lower angle is gentler than an upper angle so that most light may be extracted to the outside. Further, as illustrated in FIG. 6C, when a side surface of a first planarization layer 215a′″ is formed by a curve having a plurality of angles, most light reflected from the side surface of the first planarization layer 215a′″ may be extracted to the outside in parallel. Therefore, the light extraction efficiency may be further improved.

Even though in FIG. 5, it is illustrated that the side surface of the first planarization layer 215a has a step shape, it is not limited hereto so that the side surface of the first planarization layer 215a may be formed by a plurality of lines having a plurality of angles or formed by a curve.

Further, in a plan view, the first planarization layer 215a may have a substantially (or overall) rectangular shape, but is not limited thereto, and may have a circular, oval, or polygonal shape. Further, in a plan view, the first planarization layer 215a may have a larger area than that of the color filter layer CF to cover the color filter layer CF.

For example, the bank 116 may be formed to cover a part of a top surface of the anode 121 and a side surface of the second planarization layer 115b that is filled in the open area OA. For example, the anode 121 may be disposed in a part of the top surface of the second planarization layer 115b. A part of an end of the anode 121 may be covered by the bank 116. A part of the anode 121 that is not covered by the bank 116 to be exposed may configure the emission area EA.

The organic layer 122 may be disposed on the entire TFT substrate 110 including the open area OA.

The cathode 123 may be disposed on the organic layer 122.

According to the present disclosure, a barrier with a low refractive index may be formed at the boundary of the sub pixels, which will be described in more detail with reference to the drawing.

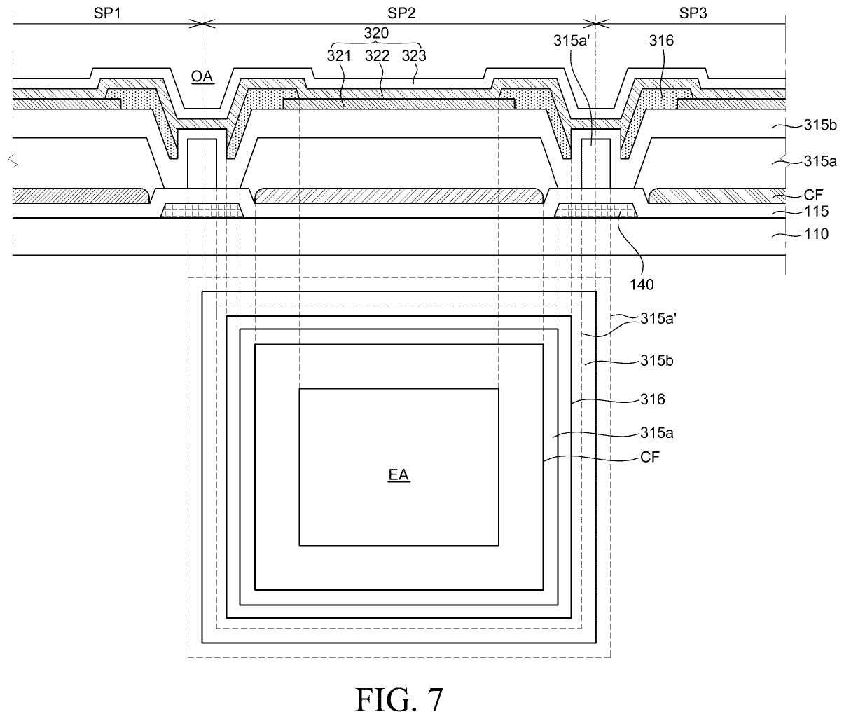

FIG. 7 is a view illustrating a cross-sectional structure and a planar structure of a display panel according to a third example embodiment of the present disclosure.

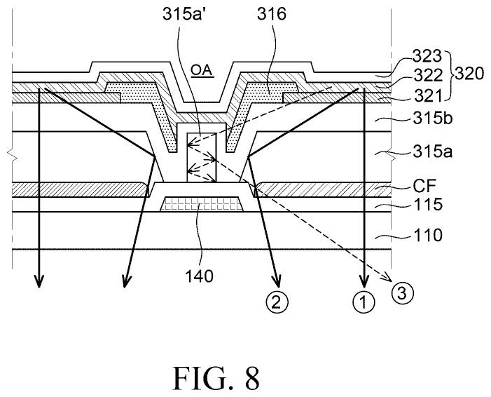

FIG. 8 is a view illustrating a cross-section of a part of a sub pixel of FIG. 7.

A difference of the third example embodiment of the present disclosure of FIGS. 7 and 8 from the above-described first example embodiment of FIGS. 3 and 4 is that a barrier 315a′ having a low refractive index is added to the boundary of the sub pixels SP1, SP2, and SP3. The other configurations are substantially the same so that a redundant description will be omitted. The same configuration will be denoted with the same reference numeral. Here, the description for the same reference numeral may refer to FIGS. 1 to 4.

FIG. 7 schematically illustrates cross-sectional structures of the first sub pixel SP1, the second sub pixel SP2, and the third sub pixel SP3 and a planar structure corresponding to the second sub pixel SP2. As a matter of convenience, FIG. 7 schematically illustrates planar structures of configurations corresponding to the second sub pixel SP2, excluding the organic layer 322 and the cathode 323 above the anode 321.

FIG. 8 illustrates a cross-sectional structure of a part of the first sub pixel SP1 and the second sub pixel SP2 illustrated in FIG. 7 together with a path of emitted light. For example, FIG. 8 illustrates a cross-sectional structure of a boundary of the first sub pixel SP1 and the second sub pixel SP2.

In FIGS. 7 and 8, for the convenience of description, a TFT substrate 110 is illustrated by omitting various circuit configurations including a thin film transistor provided on the substrate and wiring lines. Even though in FIGS. 7 and 8, components above the light emitting diode 320 are not illustrated for the convenience of description, the present disclosure is not limited thereto, and the present disclosure may include an adhesive layer, an encapsulation substrate, and the like above the light emitting diode 320.

Further, in FIGS. 7 and 8, a bottom-emission type organic light emitting display device is mainly described, but the present disclosure is not limited thereto and is also applicable to a top-emission type or a dual-emission type organic light emitting display device.

With reference to FIGS. 7 and 8, a color filter layer CF may be disposed on the protection layer 115.

The color filter layer CF may be disposed in a position corresponding to an emission area EA of each sub pixel SP1, SP2, SP3. For example, in a plan view, the color filter layer CF may have a planar size larger than the emission area EA. For example, the planar size may be an area.

A first planarization layer 315a may be disposed above the color filter layer CF. A second planarization layer 315b may be disposed on the first planarization layer 315a. For example, the second planarization layer 315b may be configured by an organic material having a higher refractive index than that of the first planarization layer 315a.

As described above, the second planarization layer 315b may be disposed on the entire TFT substrate 110 and the first planarization layer 315a may be patterned for every sub pixel SP1, SP2, SP3.

For example, according to the third example embodiment of the present disclosure, the first planarization layer 315a is patterned for every sub pixel SP1, SP2, SP3 to form the open area OA formed between the sub pixels SP1, SP2, and SP3 by removing a part of the first planarization layer 315a. The open area OA is filled with the second planarization layer 315b with a high refractive index to totally reflect light entering the adjacent sub pixel SP1, SP2, SP3, thereby suppressing the light leakage and improving the light extraction efficiency. Further, in the second example embodiment of the present disclosure, the first planarization layer 315a is formed with an appropriate thickness so that the light leakage may be suppressed without causing pixel shrinkage.

Further, in the third example embodiment of the present disclosure, a barrier 315a′ having a low refractive index is disposed in the open area OA of the boundary of the sub pixels SP1, SP2, and SP3. For example, the barrier 315a′ may be configured by an organic material having a lower refractive index than that of the second planarization layer 315b. Further, the barrier 315a′ may be configured by the same material as the first planarization layer 315a but is not limited thereto. Further, the barrier 315a′ may have the same height as the first planarization layer 315a but is not limited thereto.

Among light \textcircled{1}, \textcircled{2}, and \textcircled{3} emitted from the light emitting layer, most light \textcircled{1} is extracted to the outside via the color filter layer CF and the TFT substrate 110. Some light \textcircled{2}, which travels from the second planarization layer 315b having a high refractive index to the first planarization layer 315a with a low refractive index, is totally reflected from the interface of the first planarization layer 315a and the second planarization layer 315b to be extracted to the outside via the corresponding color filter layer CF and TFT substrate 110. Some light \textcircled{3}, which travels from the second planarization layer 315b to the barrier 315a′ of the boundary of the sub pixels SP1, SP2, and SP3, is totally reflected from the interface of the barrier 315a′ and the second planarization layer 315b to be extracted to the outside via the corresponding color filter layer CF and TFT substrate 110.

As described above, a part of the light \textcircled{2} and \textcircled{3} that travels from a corresponding sub pixel SP1, SP2, SP3 to an adjacent sub pixel SP1, SP2, and SP3 is totally reflected to be extracted to the outside via the color filter layer CF and the TFT substrate 110 of the sub pixel SP1, SP2, SP3, thereby improving light extraction efficiency.

Further, the barrier 315a′ restricts the path of light that travels to the adjacent sub pixel SP1, SP2, SP3 to suppress the color mixture with the surrounding sub pixels SP1, SP2, and SP3 to a predetermined extend.

Further, in a plan view, the first planarization layer 315a may have a substantially (or overall) rectangular shape, but is not limited thereto, and may have a circular, oval, or polygonal shape. Further, in a plan view, the first planarization layer 315a may have a larger area than that of the color filter layer CF to cover the color filter layer CF.

In a plan view, the barrier 315a′ may have a substantially (or overall) rectangular shape, but is not limited thereto, and may have a circular, oval, or polygonal shape. Further, in a plan view, the barrier 315a′ may be disposed at a boundary of the sub pixels SP1, SP2, and SP3 in a rectangular frame shape. Further, in a plan view, the barrier 315a′ may be disposed to enclose an edge of the first planarization layer 315a.

For example, the bank 316 may be formed to cover a part of a top surface of the anode 321 and a side surface of the second planarization layer 315b that is filled in the open area OA. A top surface of the second planarization layer 315b filled in the open area OA may have a step due to the barrier 315a′ but is not limited thereto.

For example, the anode 321 may be disposed in a part of the top surface of the second planarization layer 315b. A part of an end of the anode 321 may be covered by the bank 316. A part of the anode 321 that is not covered by the bank 316 to be exposed may configure the emission area EA.

The organic layer 322 may be disposed on the entire TFT substrate 110 including the open area OA.

The cathode 323 may be disposed on the organic layer 322.

In the meantime, according to the present disclosure, the above-described barrier may be formed of a black-based organic material that is different from that of the first planarization layer, which will be described in detail with reference to the drawing.

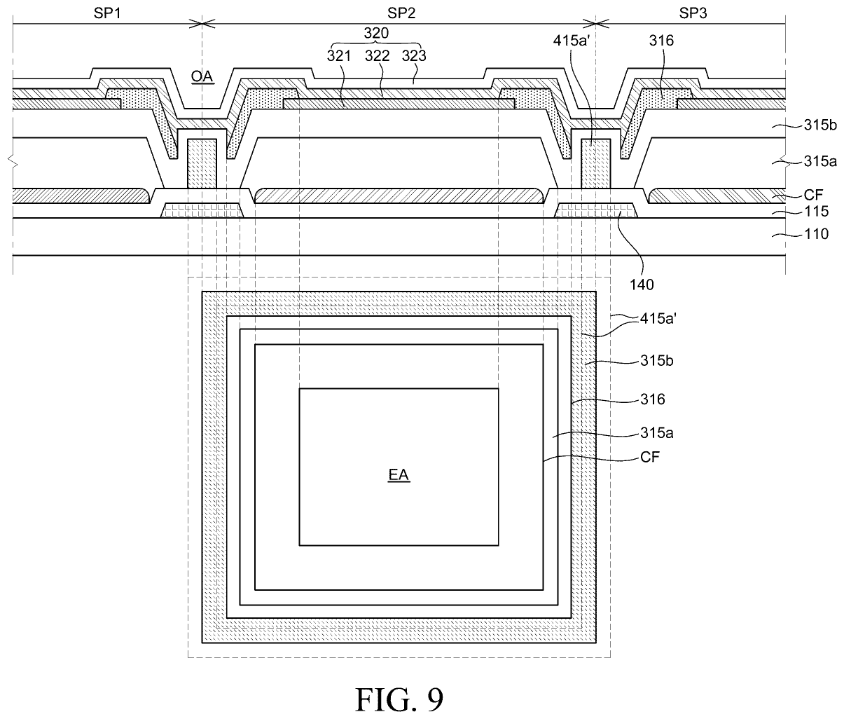

FIG. 9 is a view illustrating a cross-sectional structure and a planar structure of a display panel according to a fourth example embodiment of the present disclosure.

A difference of a fourth example embodiment of the present disclosure of FIG. 9 from the third example embodiment of the present disclosure of FIGS. 7 and 3 is that the barrier 415a′ is formed with a black-based organic material, but other configurations are substantially the same. Therefore, redundant description will be omitted. The same configuration will be denoted with the same reference numeral. Here, the description for the same reference numeral may refer to FIGS. 1 to 8.

FIG. 9 schematically illustrates cross-sectional structures of the first sub pixel SP1, the second sub pixel SP2, and the third sub pixel SP3 and a planar structure corresponding to the second sub pixel SP2. FIG. 9 schematically illustrates planar structures of configurations corresponding to the second sub pixel SP2, excluding the organic layer 322 and the cathode 323 above the anode 321.

In FIG. 9, for the convenience of description, a TFT substrate 110 is illustrated by omitting various circuit configurations including a thin film transistor provided on the substrate and wiring lines. Even though in FIG. 9, components above the light emitting diode 320 are not illustrated for the convenience of description, the present disclosure is not limited thereto, and the present disclosure may include an adhesive layer, an encapsulation substrate, and the like above the light emitting diode 320.

Further, in FIG. 9, a bottom-emission type organic light emitting display device is mainly described, but the present disclosure is not limited thereto and is also applicable to a top-emission type or a dual-emission type organic light emitting display device.

As illustrated in FIG. 9, a color filter layer CF may be disposed on the protection layer 115.

A first planarization layer 315a may be disposed above the color filter layer CF. A second planarization layer 315b may be disposed on the first planarization layer 315a. For example, the second planarization layer 315b may be configured by an organic material having a higher refractive index than that of the first planarization layer 315a.

As described above, the first planarization layer 315a is patterned for every sub pixel SP1, SP2, SP3 and an open area OA formed by removing a partial area of the first planarization layer 315a may be formed between the sub pixels SP1, SP2, and SP3. Further, in the open areas OA at the boundary of the sub pixels SP1, SP2, and SP3, a barrier 415a′ having a low refractive index may be disposed. Further, the barrier 415a′ may be configured by an organic material having a lower refractive index than that of the second planarization layer 315b.

In the meantime, according to the fourth example embodiment of the present disclosure, the barrier 415a′ may be configured by a black-based organic material that is different from the first planarization layer 315a, but it is not limited thereto.

As described above, a part of light that travels from the corresponding sub pixel SP1, SP2, SP3 to the adjacent sub pixel SP1, SP2, SP3 is totally reflected from the interface of the barrier 415a′ and the second planarization layer 315b or absorbed by the barrier 415a′. Therefore, color mixing with the surrounding sub pixels SP1, SP2, and SP3 can be effectively suppresses.

The second planarization layer 315b may be formed to cover the first planarization layer 315a and the barrier 415a′ including the open area OA.

Further, in a plan view, the first planarization layer 315a may have a substantially (or overall) rectangular shape, but is not limited thereto, and may have a circular, oval, or polygonal shape. Further, in a plan view, the first planarization layer 315a may have a larger area than that of the color filter layer CF to cover the color filter layer CF.

In a plan view, the barrier 415a′ may have a substantially (or overall) rectangular shape, but is not limited thereto, and may have a circular, oval, or polygonal shape. Further, in a plan view, the barrier 415a′ may be disposed at a boundary of the sub pixels SP1, SP2, and SP3 in a rectangular frame shape. Further, in a plan view, the barrier 415a′ may be disposed to enclose an edge of the first planarization layer 315a.

In the meantime, according to the present disclosure, both the first planarization layer and the second planarization layer are patterned for every sub pixel and a bank having a higher refractive index than that of the second planarization layer may be disposed on the side surface of the second planarization layer having a high refractive index. This will be described in more detail with reference to drawings.

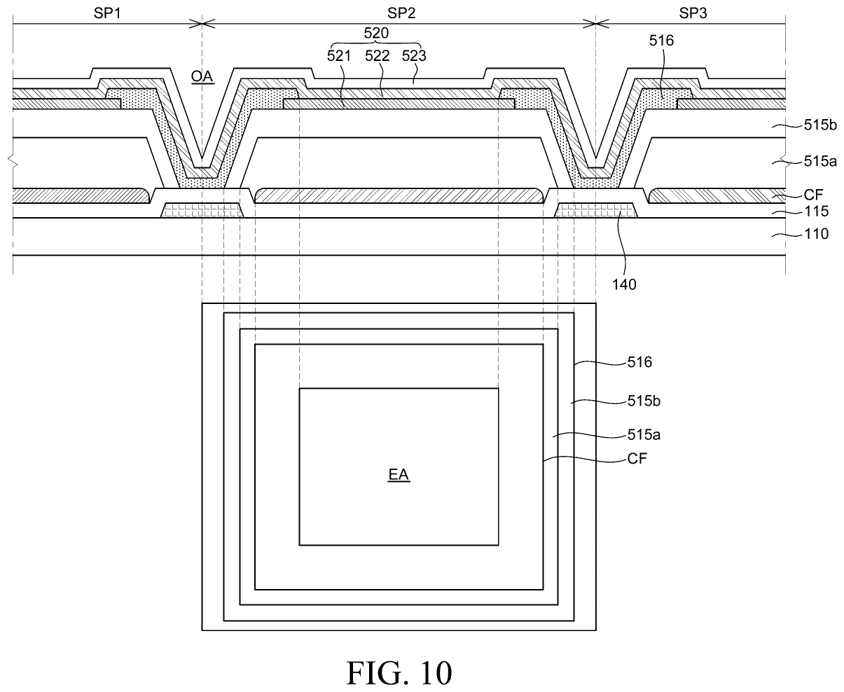

FIG. 10 is a view illustrating a cross-sectional structure and a planar structure of a display panel according to a fifth example embodiment of the present disclosure.

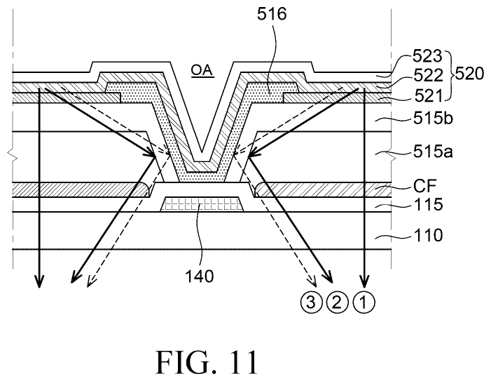

FIG. 11 is a view illustrating a cross-section of a part of a sub pixel of FIG. 10.

FIG. 10 schematically illustrates cross-sectional structures of the first sub pixel SP1, the second sub pixel SP2, and the third sub pixel SP3 and a planar structure corresponding to the second sub pixel SP2. FIG. 10 schematically illustrates planar structures of configurations corresponding to the second sub pixel SP2, excluding the organic layer 522 and the cathode 523 above the anode 521.

FIG. 11 illustrates a cross-sectional structure of a boundary of the first sub pixel SP1 and the second sub pixel SP2 illustrated in FIG. 10 together with a path of light.

In FIGS. 10 and 11, for the convenience of description, a TFT substrate 110 is illustrated by omitting various circuit configurations including a thin film transistor provided on the substrate and wiring lines. Even though in FIGS. 10 and 11, components above the light emitting diode 520 are not illustrated for the convenience of description, the present disclosure is not limited thereto, and the present disclosure may include an adhesive layer, an encapsulation substrate, and the like above the light emitting diode 520.

Further, in FIGS. 10 and 11, a bottom-emission type organic light emitting display device is mainly described, but the present disclosure is not limited thereto and is also applicable to a top-emission type or a dual-emission type organic light emitting display device.

With reference to FIGS. 10 and 11, a color filter layer CF may be disposed on the protection layer 115.

A first planarization layer 515a may be disposed on the protection layer 115. A second planarization layer 515b may be disposed on the first planarization layer 515a. For example, the second planarization layer 515b may be configured by an organic material having a higher refractive index than that of the first planarization layer 515a.

In the fifth example embodiment of the present disclosure, the first planarization layer 515a and the second planarization layer 515b may be patterned for every sub pixel SP1, SP2, SP3. For example, an open area OA that encloses the emission area EA may be disposed in the vicinity of the emission area EA of each sub pixel SP1, SP2, SP3. Here, the first planarization layer 515a and the second planarization layer 515b may be absent at the open area OA so that the open area OA goes through both the first planarization layer 515a and the second planarization layer 515b. For example, a partial area of the first planarization layer 515a between the sub pixels SP1, SP2, and SP3 is removed to form the open area OA and the second planarization layer 515b may be formed to cover the first planarization layer 515a and a part of the edge of the open area OA. Therefore, the second planarization layer 515b may expose a part of the top surface of the protection layer 115 between the sub pixels SP1, SP2, and SP3.

Further, according to the fifth example embodiment of the present disclosure, a bank 516 having a high refractive index is formed above the second planarization layer 515b to cover the exposed part of the top surface of the protection layer 115. For example, the bank 516 may be configured by an organic material having a higher refractive index than that of the second planarization layer 515b but is not limited thereto.

As described above, according to the fifth example embodiment of the present disclosure, the first planarization layer 515a is patterned for every sub pixel SP1, SP2, SP3 to form the open area OA formed between the sub pixels SP1, SP2, and SP3 by removing a part of the first planarization layer 515a. Further, the second planarization layer 515b is patterned for every sub pixel SP1, SP2, and SP3 to cover the first planarization layer 515a including a part of the edge of the open area OA. Further, according to the fifth example embodiment of the present disclosure, a bank 516 is formed on a side surface of the second planarization layer 515b to cover a side surface of the second planarization layer 515b between the sub pixels SP1, SP2, and SP3. Therefore, the second planarization layer 515b having a first high refractive index is interposed between the first planarization layer 515a having a low refractive index between the sub pixels SP1, SP2, and SP3 and the bank 516 having a second high refractive index is interposed between the second planarization layer 515b having a first high refractive index. Therefore, light entering the adjacent sub pixels SP1, SP2, and SP3 are totally reflected to suppress light leakage and further improve the light extraction efficiency. Here, the second high refractive index may be higher than the first high refractive index.

Among light \textcircled{1}, \textcircled{2}, and \textcircled{3} emitted from the light emitting layer, most light \textcircled{1} is extracted to the outside via the color filter layer CF and the TFT substrate 110. Some light \textcircled{2}, which travels from the second planarization layer 515b having a high refractive index to the first planarization layer 515a with a low refractive index, is totally reflected from the interface of the first planarization layer 515a and the second planarization layer 515b to be extracted to the outside via the corresponding color filter layer CF and TFT substrate 110. Some light \textcircled{3}, which travels from the second planarization layer 515b to adjacent sub pixels SP1, SP2, and SP3, is totally reflected from the interface of the second planarization layer 515b and the bank 516 to be extracted to the outside via the corresponding color filter layer CF and TFT substrate 110. As described above, a part of light \textcircled{2} and \textcircled{3} that travels from a corresponding sub pixel SP1, SP2, SP3 to an adjacent sub pixel SP1, SP2, SP3 is reflected to be extracted to the outside via the color filter layer CF and the TFT substrate 110 of the sub pixel SP1, SP2, SP3 to further improve the light extraction efficiency.

In the meantime, in a plan view, the first planarization layer 515a may have a substantially (or overall) rectangular shape, but is not limited thereto, and may have a circular, oval, or polygonal shape. Further, in a plan view, the first planarization layer 515a may have a larger area than that of the color filter layer CF to cover the color filter layer CF.

Further, in a plan view, the second planarization layer 515b may have a substantially (or overall) rectangular shape, but is not limited thereto, and may have a circular, oval, or polygonal shape. Further, in a plan view, the second planarization layer 515b may have an area larger than the first planarization layer 515a to cover the first planarization layer 515a.

Further, for example, in a plan view, the bank 516 may have a substantially (or overall) rectangular frame shape excluding the emission area EA, but it is not limited thereto and may have a circular, oval, or polygonal frame shape.

Further, the bank 516 may extend to adjacent sub pixels SP1, SP2, and SP3 to be filled in the open area OA.

Further, the bank 516 may be formed to cover a part of the top surface of the anode 521 while filling the open area OA.

According to embodiments of the present disclosure, the first planarization layer may be patterned for every sub pixel and a second planarization layer with a high refractive index may be interposed between the first planarization layers to totally reflect light entering the adjacent sub pixel. Accordingly, light leakage can be suppressed, and light extraction efficiency can be improved. Therefore, low power may be implemented to reduce the power consumption, and greenhouse gases generated by power use are reduced to implement environment/social/governance (ESG).

Further, a barrier with a low refractive index may be formed at a boundary of sub pixels to block or totally reflect light entering the adjacent sub pixel, thereby suppressing color mixing with surrounding sub pixels, thereby improving light extraction efficiency.

The example embodiments of the present disclosure can also be described as follows:

A display device may comprise a substrate including a plurality of sub-pixels; a first planarization layer on the substrate, the first planarization layer having an open area between adjacent ones of the sub-pixels; a second planarization layer on the first planarization layer and in the open area, the first planarization layer has a first refractive index lower than a second refractive index of the second planarization layer; a first electrode on a portion of the second planarization layer; an organic layer on the anode and in the open area; and a second electrode on the organic layer and in the open area.

The display device may further comprise a bank on a portion of a top surface of the first electrode, and on a portion of a top surface and a side surface of the second planarization layer, wherein the bank has a third refractive index that is higher than the first refractive index and lower than the second refractive index. The organic layer may further be on the bank.

The second planarization layer may be on a side surface of the first planarization layer at the open area.

The side surface of the first planarization layer may include a stepped structure.

The side surface may include a shape of at least two lines having different angles.

The display device may further comprise a barrier in the open area, the barrier having a refractive index lower than the second refractive index.

The barrier may include a same material as the first planarization layer, and the barrier has the first refractive index.

The barrier may include a black organic material.

The substrate may include a protection layer, and the barrier may be in contact with the protection layer at a central portion of the open area.

The second planarization layer may be on a side surface of the first planarization layer at the open area, and the second planarization layer may be absent at the central portion of the open area.

In another aspect, a display device having at least a first sub-pixel and a second sub-pixel may comprise a substrate; a first layer on the substrate, the first layer having an open area between the first sub-pixel and the second sub-pixel; a second layer on the first layer and in the open area, the first layer having a first refractive index that is lower than a second refractive index of the second layer; and organic light emitting devices on the second layer in each of the first sub-pixel and the second sub-pixel.

The display device may further comprise a bank on at least a portion of the second transparent layer at a side of the open area.

The bank may have a third refractive index that is higher than the first refractive index and lower than the second refractive index.

The second layer may be on a side surface of the first layer at the open area, and the side surface of the first layer may include a stepped structure.

The second layer may include a shape of at least two lines having different angles.

The second layer may be on a side surface of the first layer at the open area, and the side surface of the first layer may include a curved structure.

The display device may further comprise a barrier in the open area, the barrier having a refractive index lower than the second refractive index.

The barrier may include a same material as the first layer, and the barrier may have the first refractive index.

The barrier may include a black organic material.

The substrate may include a protection layer, wherein the barrier is in contact with the protection layer at a central portion of the open area, and wherein the second layer is on a side surface of the first layer at the open area, and the second layer is absent at the central portion of the open area.

The first layer and the second layer may be transparent layers.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including a plurality of sub-pixels;
a first planarization layer on the substrate, the first planarization layer having an open area between adjacent ones of the sub-pixels;
a second planarization layer on the first planarization layer and in the open area, the first planarization layer has a first refractive index lower than a second refractive index of the second planarization layer;
a first electrode on a portion of the second planarization layer;
an organic layer on the anode and in the open area; and
a second electrode on the organic layer and in the open area.

2. The display device according to claim 1, further comprising a bank on a portion of a top surface of the first electrode, and on a portion of a top surface and a side surface of the second planarization layer,
wherein the bank has a third refractive index that is higher than the first refractive index and lower than the second refractive index.

3. The display device according to claim 1, wherein the second planarization layer is on a side surface of the first planarization layer at the open area.

4. The display device according to claim 3, wherein the side surface of the first planarization layer includes a stepped structure.

5. The display device according to claim 3, wherein the side surface includes a shape of at least two lines having different angles.

6. The display device according to claim 1, further comprising a barrier in the open area, the barrier having a refractive index lower than the second refractive index.

7. The display device according to claim 6, wherein the barrier includes a same material as the first planarization layer, and the barrier has the first refractive index.

8. The display device according to claim 6, wherein the barrier includes a black organic material.

9. The display device according to claim 6, wherein the substrate includes a protection layer, and
wherein the barrier is in contact with the protection layer at a central portion of the open area.

10. The display device according to claim 9, wherein the second planarization layer is on a side surface of the first planarization layer at the open area, and wherein the second planarization layer is absent at the central portion of the open area.

11. A display device having at least a first sub-pixel and a second sub-pixel, comprising:
a substrate;
a first layer on the substrate, the first layer having an open area between the first sub-pixel and the second sub-pixel;
a second layer on the first layer and in the open area, the first layer having a first refractive index that is lower than a second refractive index of the second layer; and
organic light emitting devices on the second layer in each of the first sub-pixel and the second sub-pixel.

12. The display device according to claim 11, further comprising a bank on at least a portion of the second transparent layer at a side of the open area.

13. The display device according to claim 12, wherein the bank has a third refractive index that is higher than the first refractive index and lower than the second refractive index.

14. The display device according to claim 11, wherein the second layer is on a side surface of the first layer at the open area, and wherein the side surface of the first layer includes a stepped structure.

15. The display device according to claim 11, wherein the second layer includes a shape of at least two lines having different angles.

16. The display device according to claim 11, wherein the second layer is on a side surface of the first layer at the open area, and wherein the side surface of the first layer includes a curved structure.

17. The display device according to claim 11, further comprising a barrier in the open area, the barrier having a refractive index lower than the second refractive index.

18. The display device according to claim 17, wherein the barrier includes a same material as the first layer, and the barrier has the first refractive index.

19. The display device according to claim 17, wherein the barrier includes a black organic material.

20. The display device according to claim 18, wherein the substrate includes a protection layer,
wherein the barrier is in contact with the protection layer at a central portion of the open area, and
wherein the second layer is on a side surface of the first layer at the open area, and the second layer is absent at the central portion of the open area.

21. The display device according to claim 11, wherein the first layer and the second layer are transparent layers.
